(19) United States
(12) Patent Application Publication
(10) Pub. No.: US 2010/0300731 A1
(43) Pub. Date: Dec. 2, 2010

(54) FLEXIBLE CIRCUIT BOARD MATERIAL AND METHOD FOR PRODUCING THE SAME

(75) Inventors: Steffen Guenther, Dresden (DE); Waldemar Schoenberger, Dresden (DE); Steffen Straach, Dresden (DE); Nicolas Schiller, Stolpen OT Helmsdorf (DE); Volker Kirchhoff, Wehlen (DE)

Correspondence Address: GREENBLUM & BERNSTEIN, P.L.C., 1950 ROLAND CLARKE PLACE, RESTON, VA, 20191, US

(73) Assignee: FRAUNHOFER-GESELLSCHAFT ZUR FÖRDERUNG DER ANGEWANDTEN FORSCHUNG E.V., München (DE)

(21) Appl. No.: 12/599,651

(22) PCT Filed: May 7, 2008
(86) PCT No.: PCT/EP2008/003678

§ 371 Date: Nov. 10, 2009

(30) Foreign Application Priority Data
May 10, 2007 (DE) 10 2007 021 896.8

(51) Int. Cl. H05K 1/09; C23C 14/35

(52) U.S. Cl. 174/254; 204/192.14; 174/257

(57) ABSTRACT

A method for producing a flexible circuit board material having a polymer substrate and a copper layer. The method includes depositing a layer of titanium oxide to be between the polymer substrate and the copper layer. The layer of titanium oxide and the copper layer are deposited using vacuum methods.

### CROSS REFERENCE TO RELATED APPLICATIONS

The present application is a U.S. National Stage of International Application No. PCT/EP2008/003678 filed May 7, 2008, which published as WO 2008/138532 A1 on Nov. 20, 2008, the disclosure of which is expressly incorporated by reference herein in its entirety. Further, this application claims priority under 35 U.S.C. §119 and §365 of German Application No. 10 2007 021 896.8 filed May 10, 2007.

### BACKGROUND OF THE INVENTION

1. Field of the Invention

The invention relates to a flexible circuit board material, comprising a polymer substrate with a copper coating and a method for producing a flexible circuit board material of this type.

Polyimide coated with copper is primarily used for the production of flexible circuit boards. Polyimide is characterized by a high thermal and chemical stability and is therefore able to cope with the stresses of the individual process steps in the production of the circuit board material, such as the galvanic reinforcement of an applied copper layer, a subsequent structuring of the copper layer by an etching solution or an ultimate equipment of the circuit board material with the functional elements by flow soldering or dip soldering.

In addition to the stability of the polyimide in the course of the referenced process steps, the adhesion of the copper layer on the polyimide during the production and the service life of the circuit board material is of crucial importance. Various methods have already been tested to achieve a firmly adhered connection of a copper layer to polyimide. However, a satisfactory solution has hitherto not been found.

2. Background Description

It is known, for example, to subject the surface of a polyimide film to a reactive ion etching treatment before a copper layer is deposited on the polyimide film (Arthur L. Ruoff et al., Improvement of adhesion of copper on polyimide by reactive ion-beam etching, IBM J. Res. Develop., 1988, Vol. 32, p. 626-630). Although breaking down the polymer structures of the substrate through the ion etching treatment promotes the adhesive strength of a copper layer deposited thereon, at the same time it causes a change in the material properties of the substrate.

To improve the adhesive properties of a copper layer it has furthermore been proposed to deposit adhesion promoter layers between a polyimide substrate and a copper layer. Thus, for example, sublayers of Cr or NiCr are known to improve the adhesion of a copper layer (K. J. Blackwell et al., Enhancement of Chromium-to-Polyimide Adhesion by Oxygen DC Glow Treatment Prior to Roll-Sputter Seeding, Society of Vacuum Coaters, 1992, p. 279-283). One disadvantage of a solution of this type is that during the etching of the conductor path structures, in which the Cr or NiCr layer also has to be etched under the copper layer, carcinogenic Cr-VI compounds are produced. A further disadvantage is that through etching solutions adapted to copper, an underetching of the conductor path structures occurs when these etching solutions meet the Cr or NiCr layer.

Further metallic materials are disclosed in JP 2003011272 A, which are suitable as adhesion promoters between a polyimide film and a copper layer. In the structuring of a circuit board material of this type, base layers of this type must be completely removed outside the copper conductor paths, because these electrically conductive base layers would otherwise produce an electrical short circuit between the conductor paths. Etching solutions for structuring circuit board material, however, are designed in their etching effect especially for etching copper. Thus, with the etching solutions used, the metallic base layers are often not completely removed between the conductor paths, or the underetching of conductor path structures already described above occurs again.

### SUMMARY OF THE INVENTION

The technical aim of the invention is therefore to create a flexible circuit board material and a method for the production thereof, by which the disadvantages of the prior art are overcome. In particular, the copper layer of the circuit board material should have a high adhesive strength on the substrate material and a structuring of conductor paths on the circuit board material by etching processes should be possible.

The solution of the technical aim is shown by a method for producing a flexible circuit board material, comprising a polymer substrate and a copper layer, characterized in that a layer of titanium oxide is deposited between the polymer substrate and the copper layer, wherein the layer of titanium oxide and the copper layer are deposited by vacuum methods; and by a flexible circuit board material comprising a polymer substrate and a copper layer, characterized in that a layer of titanium oxide is deposited between the polymer substrate and the copper layer. Further advantageous embodiments of the invention are shown by the dependent claims.

In a method according to the invention for producing a flexible circuit board material, comprising a polymer substrate and a copper layer, a dielectric layer is deposited between the polymer substrate and the copper layer, wherein the dielectric layer and the copper layer are deposited by vacuum methods.

A dielectric intermediate layer deposited in this manner combines two advantages. On the one hand, an intermediate layer of this type, which can be deposited with a layer thickness of up to 100 nm, acts as an excellent adhesion promoter between the polymer substrate and the copper layer. On the other hand, a dielectric layer of this type does not exhibit electric conductivity and therefore does not need to be removed between the conductor paths during the structuring of the conductor paths. The conventional etching solutions, which are designed in particular for etching copper material, can therefore be used in the structuring of the wiring tracks.

A dielectric layer can be deposited, for example, as a oxide or mixed oxide. Ti, Zn, Nb, Mo, Sn or Ta, for example, are suitable as elements for an oxide layer or mixed oxide layer of this type. The oxide layer or mixed oxide layer can also be doped with further elements. A layer of titanium oxide is particularly suitable as a dielectric layer, because titanium oxide acts as an excellent adhesion promoter between a polymer substrate and a copper layer.

In one embodiment, the titanium oxide layer is deposited as a titanium dioxide layer between the polymer substrate and the copper layer.

Alternatively, the dielectric layer can also be deposited from a nitride or oxynitride. A layer of this type of a nitride or oxynitride can be formed, for example, from the elements Ti, Zn, Nb, Mo, Sn, Ta or Si.

Magnetron sputtering methods are suitable for depositing a dielectric intermediate layer, because with magnetron sputtering methods very small layer thicknesses in the layer thickness range of only a few nanometers with constant layer properties can also be deposited. Thus, for example, a dual magnetron, which is operated in the medium frequency (MF) range from 5 kHz to 250 kHz, can be used for layer deposition. Alternatively, however, a radio frequency (RF) magnetron can also be used. Magnetron sputtering methods can be carried out reactively as well as non-reactively.

In another embodiment, an oxide layer is deposited in that a titanium target is sputtered in the presence of the reactive gas oxygen. A particularly simple process control can be implemented here when the titanium target is sputtered in the fully reactive mode, because the fully reactive mode represents a stable process state. Furthermore, with a fully reactive mode it is ensured that a fully stoichiometric titanium oxide layer is deposited.

For depositing a dielectric layer, however, electron beam evaporation or also a CVD method can be used, wherein each of these methods can be carried out with or without plasma support.

Also when depositing the copper layer, alternatively either magnetron sputtering or evaporation from boats or by electron beam can be used, wherein the evaporation again can be carried out with or without plasma support.

It is particularly advantageous if the dielectric layer and the copper layer are deposited immediately following one another and without vacuum break, because a particularly strong layer bond is obtained thereby.

If constant layer properties are to be implemented over the entire surface of a polymer substrate, the polymer substrate must be moved at a constant speed during the coating process.

In a further embodiment the copper layer is reinforced by a galvanic method after the deposition by a vacuum method.

A flexible circuit board material according to the invention comprises a polymer substrate and a copper layer, wherein a dielectric layer is deposited between the polymer substrate and the copper layer.

The polymer substrate can comprise one of the materials polyimide, PEN, PEEK, PET or fluorocarbon polymer and can be embodied as a film or alternatively as a non-woven fabric or a woven fabric.

Layer thicknesses of up to 100 nm are suitable for the dielectric layer. A dielectric layer can be embodied, for example, as an oxide or mixed oxide of the elements Ti, Zn, Nb, Mo, Sn or Ta, wherein the oxide or mixed oxide can have other doping elements. If the dielectric layer is embodied as a titanium dioxide layer, a layer thickness of 75 nm is already sufficient as an upper limit. However, with a layer of titanium dioxide as an adhesion promoter layer, very good adhesion results are also already achieved at layer thicknesses below 30 nm.

Alternatively, a dielectric layer can be embodied as a nitride or oxynitride, such as, for example, of the elements Ti, Si, Zn, Nb, Mo, Sn or Ta.

In one embodiment, the copper layer of the flexible circuit board material has an adhesive strength of at least 6 N/cm, measured according to IPC standard 650.

### BRIEF DESCRIPTION OF THE DRAWING

The invention is explained in more detail below based on a preferred exemplary embodiment.

FIG. 1 shows a flexible circuit board material 1 according to the invention diagrammatically in section.

### DETAILED DESCRIPTION OF THE INVENTION

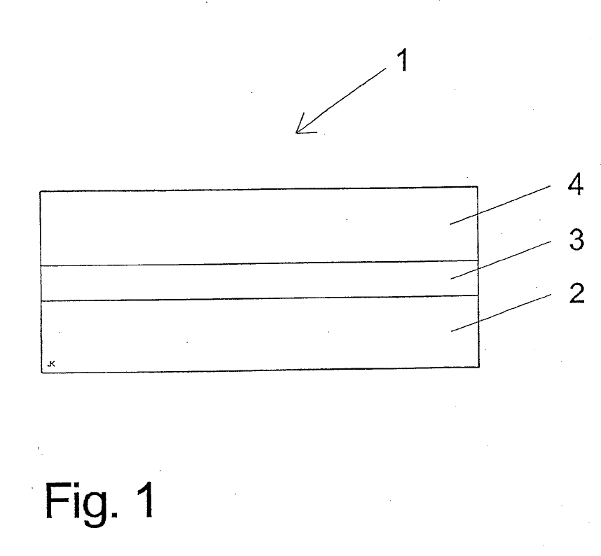

As shown in FIG. 1, a 6 nm-thick TiO₂ layer 3 was deposited by MF sputtering on a 25 μm-thick polyimide (Kapton HN) substrate 2. A titanium target was thereby sputtered in oxidic mode in the presence of the reactive gas oxygen in a first vacuum chamber by a double magnetron, which was operated in the medium frequency range at 40 kHz. Without interrupting the vacuum, immediately thereafter the deposition of a copper layer 4 approximately 100 nm thick was carried out in a second vacuum chamber. A single magnetron operated with direct voltage was used for the deposition of the copper layer 4. The sputtered-on copper layer 4 was subsequently galvanically reinforced to a total layer thickness of approximately 20 μm.

It was possible to measure a value of 12.0 N/cm for the adhesive strength of the copper layer 4 on the substrate 2 according to IPC standard 650. However, without the TiO₂ layer 3, an adhesive strength of only 4 N/cm was achieved with comparison samples.

1.-17. (canceled)

18. A method for producing a flexible circuit board material having a polymer substrate and a copper layer, the method comprising:
depositing a layer of titanium oxide to be between the polymer substrate and the copper layer,
wherein the layer of titanium oxide and the copper layer are deposited using vacuum methods.

19. The method of claim 18, wherein the layer of titanium oxide comprises titanium dioxide.

20. The method of claim 18, wherein the depositing the layer of titanium oxide comprises magnetron sputtering.

21. The method of claim 20, wherein the depositing the layer of titanium oxide comprises using a dual magnetron operated in a medium frequency range.

22. The method of claim 21, wherein the dual magnetron is operated in a frequency range from 5 kHz to 250 kHz.

23. The method of claim 20, wherein the depositing the layer of titanium oxide comprises using a radio frequency magnetron.

24. The method of claim 20, wherein the depositing the layer of titanium oxide comprises sputtering a titanium target in the presence of a reactive gas oxygen.

25. The method of claim 24, wherein the titanium target is sputtered in a fully reactive mode.

26. The method of claim 18, wherein the depositing the copper layer comprises magnetron sputtering.

27. The method of claim 18, wherein the depositing the layer of titanium oxide is immediately followed by the depositing of the copper layer without a vacuum break.

28. The method of claim 18, wherein the layer of titanium oxide is deposited with a thickness of less than 100 nm.

29. A flexible circuit board material, comprising:
a polymer substrate;
a layer of titanium dioxide; and
a copper layer, wherein the layer of titanium oxide is deposited between the polymer substrate and the copper layer.

30. The flexible circuit board material of claim 29, wherein the polymer substrate comprises one of polyimide, PEN, PEEK, PET and fluorocarbon polymer.

31. The flexible circuit board material of claim 29, wherein the layer of titanium oxide comprises a thickness of less than 100 nm.

32. The flexible circuit board material of claim 29, wherein the layer of titanium oxide comprises a layer of titanium dioxide.

33. The flexible circuit board material of claim 32, wherein the layer of titanium dioxide comprises a thickness of less than 75 nm.

34. The flexible circuit board material of claim 33, wherein the layer of titanium dioxide comprises a thickness of less than 30 nm.

35. The flexible circuit board material of claim 29, wherein the copper layer comprises an adhesive strength of at least 6 N/cm, measured according to IPC standard 650.

36. A method for producing a flexible circuit board material having a polymer substrate and a copper layer, the method comprising:
depositing a layer of titanium oxide on the polymer substrate; and
depositing the copper layer, such that the layer of titanium oxide is arranged between the polymer substrate and the copper layer,
wherein the depositing the layer of titanium oxide and the depositing the copper layer are deposited using vacuum methods.
